(19) United States
(12) Patent Application Publication
(10) Pub. No.: US 2026/0243520 A1
(43) Pub. Date: Aug. 20, 2026

(54) FIXING ASSEMBLY AND SWITCHING ELEMENT COMPRISING SAME

(71) Applicant: LG INNOTEK CO., LTD., Seoul (KR)

(72) Inventors: Mi Sun LEE, Seoul (KR); Dong Keun YOON, Seoul (KR); Ji Hwan JEON, Seoul (KR)

(21) Appl. No.: 19/469,614

(22) PCT Filed: Feb. 2, 2024
(86) PCT No.: PCT/KR2024/001621

§ 371 Date: Sep. 26, 2025

(30) Foreign Application Priority Data
Mar. 29, 2023 (KR) 10-2023-0041549
Jan. 16, 2024 (KR) 10-2024-0007025

(51) Int. Cl. F28F 3/02; H01H 9/52

(52) U.S. Cl. CPC F28F 3/025; H01H 9/52; F28F 2215/00

(57) ABSTRACT

A fixing assembly according to an embodiment of the present invention comprises: a heat dissipation member including, on one surface thereof, a base on which a switching element is disposed, and on the other surface thereof, a plurality of heat dissipation fins protruding from the base; and a fixing member that is inserted from one side to the other side of the heat dissipation member to fix the switching element and the heat dissipation member to each other, wherein the fixing member has a clip shape that presses the switching element toward the heat dissipation member.

### TECHNICAL FIELD

The present invention relates to a fixing assembly and a switching element including the same.

### BACKGROUND ART

Various electronic components constituting electronic products are mounted on a printed circuit board on which circuit patterns are printed. Such electronic components are provided with switching elements for applying power to other electronic components. And the switching element is fixed by a fixing assembly.

The switching element must be stably fixed to the substrate for signal transmission and electrical connection. In addition, a switching element is an electronic component that generates heat and needs to be fixed by a structure with high heat dissipation efficiency.

### DETAILED DESCRIPTION OF THE INVENTION

### Technical Subject

The technical problem to be solved by the present invention is to provide a fixing assembly and a switching element including the same.

### Technical Solution

In order to solve the above technical problem, the fixing assembly according to the embodiment of the present invention comprises: a heat dissipation member including, on one surface thereof, a base on which a switching element is disposed, and on the other surface thereof, a plurality of heat dissipation fins being protruded from the base; and a fixing member being inserted from one side to the other side of the heat dissipation member to fix the switching element and the heat dissipation member to each other, wherein the fixing member has a clip shape that presses the switching element toward the heat dissipation member.

An insulation layer may be disposed between the switching element and the heat dissipation member, and an insulation member being disposed on the other side of the heat dissipation member may be included.

The base of the heat dissipation member includes a first step and a second step being protruded outward, and the insulation layer can be disposed between the first step and the second step.

The fixing member includes a first region in which a first hole is formed, the heat dissipation member has a second hole formed at a position corresponding to the first hole of the fixing member, and a screw penetrating the first hole and the second hole may be disposed.

The heat dissipation member may include two protruded portions being protruded in one direction from the first surface on which the first region of the fixing member is disposed, and a groove being formed between the two protruded portions.

The first region of the fixing member may include a first portion having a first length, a second portion having a second length smaller than the first length, and a catching part being in contact with one surface of the two protruded portions between the first portion and the second portion.

The second length of the second portion may be formed to correspond to the groove of the heat dissipation member.

The fixing member may include a first region in which a first hole is formed, a second region being extended from the first region in a direction toward the heat dissipation fin, a third region being extended from the second region and being bent, a fourth region being extended from the first region and being bent in a direction toward the base, a fifth region being extended from the fourth region, and a sixth region being extended from the fifth region.

At least a portion of the fifth region and the sixth region of the fixing member may be in contact with the switching element.

The second region of the fixing member may include a hole shape.

### Advantageous Effects

According to the present embodiments, the switching element can be stably fixed on the substrate and heat dissipation can be enhanced. Furthermore, the structure in which it is inserted and fixed from one direction can ensure ease of assembly.

### BRIEF DESCRIPTION OF DRAWINGS

FIG. 1 is a perspective view of a fixing assembly according to the present embodiment.

FIG. 2 is an exploded perspective view of a fixing assembly according to the present embodiment.

FIG. 3 is a perspective view of a heat dissipation member and fixing member of a fixing assembly according to the present embodiment.

FIG. 4 is a top view of a fixing assembly according to the present embodiment.

FIG. 5 is a side view of a fixing assembly according to the present embodiment.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention. In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used.

These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

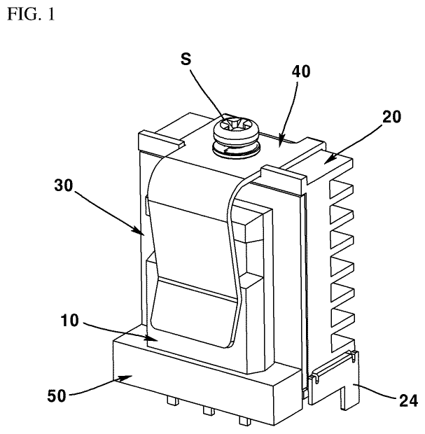

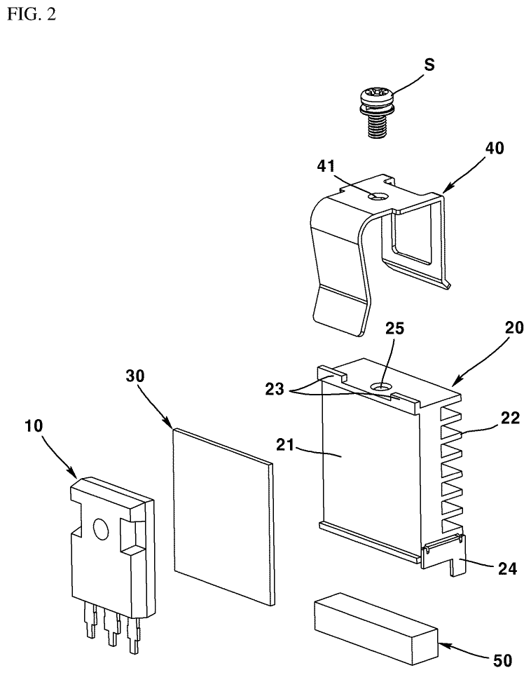

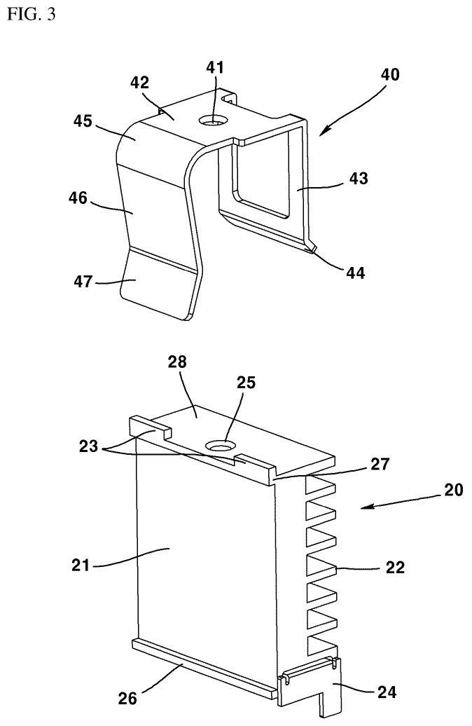

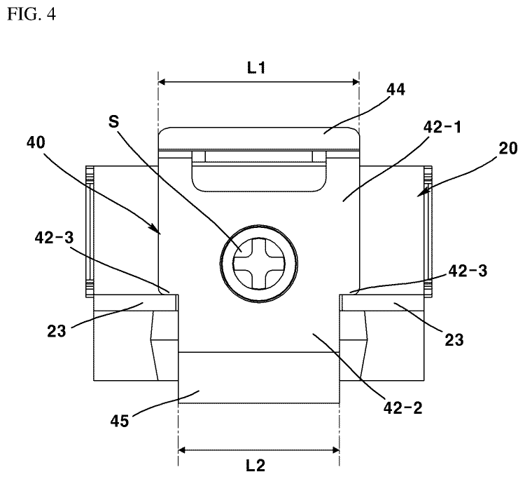

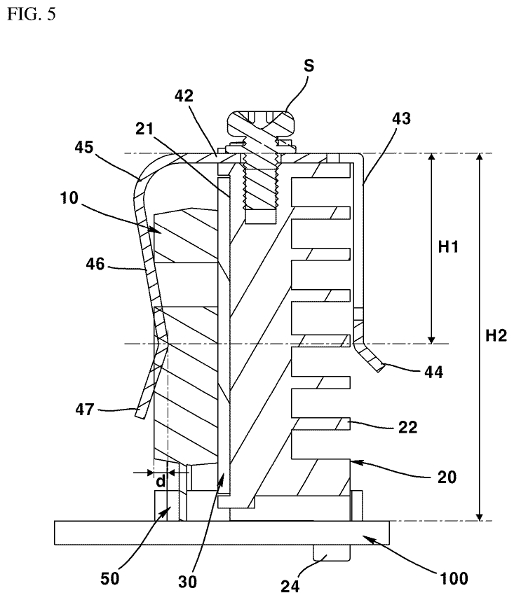

FIG. 1 is a perspective view of a fixing assembly according to the present embodiment; FIG. 2 is an exploded perspective view of a fixing assembly according to the present embodiment; FIG. 3 is a perspective view of a heat dissipation member and fixing member of a fixing assembly according to the present embodiment; FIG. 4 is a top view of a fixing assembly according to the present embodiment; and FIG. 5 is a side view of a fixing assembly according to the present embodiment.

The fixing assembly according to the present embodiment may include a heat dissipation member 20 and a fixing member 40, and may include an insulation layer 30 and an insulation member 50. The fixing assembly may be referred to as a bracket.

The heat dissipation member 20 may include a base 21 on one surface of which a switching element 10 is disposed. An insulation layer 30 may be disposed on one surface of the base 21. A switching element 10 may be disposed on one surface of the base 21. An insulation layer 30 may be disposed between the base 21 and the switching element 10. The insulation layer 30 may be formed in a sheet shape.

A plurality of heat dissipation fins 22 may be formed to be protruded from the other surface of the heat dissipation member 20. The heat dissipation member 20 may include a plurality of heat dissipation fins 22 being protruded from the base 21. The heat dissipation fin 22 may include a plurality of heat dissipation fins 22 being spaced apart from each other. The plurality of heat dissipation fins 22 may be formed in parallel to each other. A recessed portion may be formed between the plurality of heat dissipation fins 22. As the contact area with air increases through the plurality of heat dissipation fins 22, heat being generated from the switching element 10 can be dissipated. The heat dissipation member 20 may be referred to as a heat sink.

Steps may be formed on one side and the other side of the base 21. The base 21 may include a first step 26 and a second step 27 being protruded outward. An insulation layer 30 may be disposed between the first step 26 and the second step 27. The position of the insulation layer 30 may be supported through the steps formed on the base 21. The insulation layer 30 may be disposed between the switching element 10 and the heat dissipation member 20 to perform an insulating function. The insulation layer 30 may be made of a ceramic material. The insulation layer 30 may be referred to as an insulating plate.

The heat dissipation member 20 may include a first surface on which a first region 42 of the fixing member 40 is disposed. A hole 25 may be formed on an upper surface of the heat dissipation member 20. A screw S may be inserted into the hole 25 and coupled. The hole 25 of the heat dissipation member 20 may correspond to the hole 41 of the fixing member 40. The hole 25 of the heat dissipation member 20 and the hole 41 of the fixing member 40 are disposed to be overlapped with each other, and the screw S may be coupled by penetrating each hole. The hole 25 of the heat dissipation member 20 may be referred to as a first hole, and the hole 41 of the fixing member 40 may be referred to as a second hole.

The upper surface of the heat dissipation member 20 may include a protruded portion 23 being protruded upward. The protruded portion 23 may be formed to be protruded upward from both side surfaces. The protruded portion 23 may include two protruded portions 23 being spaced apart from each other. A groove in which a fixing member 40 is disposed may be included between the two protruded portions 23. The protruded portion 23 may serve as a stopper for the fixing member 40.

The other side of the heat dissipation member 20 may include a lead 24 being inserted and fixed into the substrate 100. The lead 24 may be formed to be extended downward by being coupled to a side surface of the heat dissipation member 20. The lead 24 may be formed in ‘¬’ shape.

The switching element 10 may be an FET element or a diode element. The switching element 10 may include a body and a plurality of pins being extended from the body and connected to the substrate 100. An insulation member 50 may be disposed on a lower surface of the body of the switching element 10.

An insulation member 50 may be disposed between the switching element 10 and the substrate 100. The insulation member 50 may be disposed between the switching element 10 and the substrate 100 to perform an insulating function. The insulation member 50 may be made of a silicone material or a rubber material. The insulation member 50 may be disposed on the other side of the heat dissipation member 20. The insulation member 50 may be disposed between the substrate 100 and the base 21. The insulation member 50 may be disposed between the base 21 and the lead 24. The insulation member 50 may serve to support the base 21 being disposed on the substrate 100.

The fixing member 40 may be formed in a clip shape. The fixing member 40 may have a clip shape that presses the switching element 10 toward the heat dissipation member 20. The fixing member 40 may be formed to surround the base 21, the heat dissipation fin 22, and the first surface 28 connecting the base 21 and the heat dissipation fin 22 of the heat dissipation member 20. The fixing member 40 may be inserted from one side of the heat dissipation member 20 toward the other side to fix the switching element 10 and the heat dissipation member 20.

The fixing member 40 may include a first region 42 in which a hole 41 is formed. The first region 42 may be disposed on an upper surface of the heat dissipation member 20. The first region 42 of the fixing member 40 may include a first portion 42-1 having a first length L1, a second portion 42-2 having a second length L2 smaller than the first length L1, and a catching part 42-3 being in contact with one surface of two protruded portions 23 between the first portion 42-1 and the second portion 42-2. Through this, the position of the fixing member 40 may be fixed on the heat dissipation member 20.

The fixing member 40 may include a second region 43 being extended from the first region 42 toward the heat dissipation fin 22, a third region 44 being extended from the second region 43 and being bent. The fixing member 40 may include a fourth region 45 being extended from the first region 42 toward the base 21 and being bent, a fifth region 46 being extended from the fourth region 45, and a sixth region 47 being extended from the fifth region 46. The first region 42 to the sixth region 47 are used to conveniently refer to one fixing member 40, and the fixing member 40 may include additional regions in addition to the first region 42 to the sixth region 47, and any one among the first region 42 to the sixth region 47 may be omitted. The second region 43 and the third region 44 of the fixing member 40 may face the heat dissipation fin 22, and the fourth to sixth regions 45, 46 and 47 may face the switching element 10 or the base 21.

The second region 43 of the fixing member 40 may be extended in a vertical direction relative to the first region 42. The second region 43 may include a hole shape. The hole shape of the second region 43 allows the heat dissipation fin 22 to be exposed to the outside, thereby increasing heat dissipation efficiency.

At least a portion of the second region 43 and the third region 44 of the fixing member 40 may be in contact with the heat dissipation fin 22. The second region 43 and the third region 44 of the fixing member 40 may not be in contact with the heat dissipation fin 22. The second region 43 and the third region 44 of the fixing member 40 may be formed to have an obtuse angle. This allows the fixing member 40 to serve as a guide when it is inserted while surrounding the outer surface of the heat dissipation member 20, thereby facilitating assembly.

The fourth region 45 of the fixing member 40 may be formed into a curved surface. The fourth region 45 may be formed into a bent shape. The fifth region 46 of the fixing member 40 may be extended from the fourth region 45 and come into contact with the switching element 10. The sixth region 47 of the fixing member 40 may be formed to have an obtuse angle with the fifth region 46. Through this, when the fixing member 40 is inserted while surrounding the outer surface of the heat dissipation member 20, it may serve as a guide and facilitate assembly.

At least a portion of the fifth region 46 and the sixth region 47 of the fixing member 40 may be in contact with the switching element 10. The fifth region 46 and the sixth region 47 of the fixing member 40 may have a region d being overlapped with the switching element 10. The fixing member 40 may stably fix the switching element 10 through a seesaw effect via the region d being overlapped with the switching element 10.

Referring to FIG. 5, which illustrates a side view of a fixing assembly according to an embodiment of the present invention, a line connecting the boundary points of the second region 43 and the third region 44 of the fixing member 40 and the boundary points of the fifth region 46 and the sixth region 47 may be formed on an imaginary line. The length H1 from the first region 42 to the second region 43 of the fixing member 40 may be formed as half the length H2 from the first region 42 to the substrate 100. The length H1 from the first region 42 of the fixing member 40 to the boundary points of the fifth region 46 and the sixth region 47 may be formed as half the length H2 from the first region 42 to the substrate 100. Through this, the fixing member can more stably fix the switching element and heat dissipation member.

Those skilled in the art related to the present embodiment will understand that the above-described description can be implemented in a modified form without departing from the essential characteristics thereof. Therefore, the disclosed methods should be considered from an illustrative rather than a restrictive perspective. The scope of the present invention is indicated by the claims, not the above description, and all differences within the scope equivalent thereto should be interpreted as being included in the present invention.

1. A fixing assembly comprising:
a heat dissipation member comprising, on one surface thereof, a base on which a switching element is disposed, and on the other surface thereof, a plurality of heat dissipation fins being protruded from the base; and
a fixing member being inserted from one side to the other side of the heat dissipation member to fix the switching element and the heat dissipation member to each other,
wherein the fixing member has a clip shape that presses the switching element toward the heat dissipation member.

2. The fixing assembly according to claim 1,
wherein an insulation layer is disposed between the switching element and the heat dissipation member, and
wherein an insulation member being disposed on the other side of the heat dissipation member is comprised.

3. The fixing assembly according to claim 2,
wherein the base of the heat dissipation member comprises a first step and a second step being protruded outward, and
wherein the insulation layer is disposed between the first step and the second step.

4. The fixing assembly according to claim 1,
wherein the fixing member comprises a first region in which a first hole is formed,
wherein the heat dissipation member has a second hole formed at a position corresponding to the first hole of the fixing member, and
wherein a screw penetrating the first hole and the second hole is disposed.

5. The fixing assembly according to claim 4,
wherein the heat dissipation member comprises two protruded portions being protruded in one direction from the first surface on which the first region of the fixing member is disposed, and a groove being formed between the two protruded portions.

6. The fixing assembly according to claim 5,
wherein the first region of the fixing member comprises a first portion having a first length, a second portion having a second length smaller than the first length, and a catching part being in contact with one surface of the two protruded portions between the first portion and the second portion.

7. The fixing assembly according to claim 6,
wherein the second length of the second portion is formed to correspond to the groove of the heat dissipation member.

8. The fixing assembly according to claim 1,
wherein the fixing member comprises a first region in which a first hole is formed, a second region being extended from the first region in a direction toward the heat dissipation fin, a third region being extended from the second region and being bent, a fourth region being extended from the first region and being bent in a direction toward the base, a fifth region being extended from the fourth region, and a sixth region being extended from the fifth region.

9. The fixing assembly according to claim 8,
wherein at least a portion of the fifth region and the sixth region of the fixing member is in contact with the switching element.

10. The fixing assembly according to claim 8,
wherein the second region of the fixing member comprises a hole shape.

11. The fixing assembly according to claim 8,
wherein the second region and the third region of the fixing member are not in contact with the heat dissipation member.

12. A fixing assembly comprising:
a heat dissipation member in which a switching element is disposed and which comprises a heat dissipation fin; and
a fixing member fixing the switching element and the heat dissipation member,
wherein the fixing member comprises a first region in which a first hole is formed, a second region extended from the first region in a direction toward the heat dissipation fin, a third region extended from the second region and being bent, a fourth region extended from the first region and being bent in a direction toward the base, a fifth region extended from the fourth region, and a sixth region extended from the fifth region.

13. The fixing assembly according to claim 12, further comprising:
an insulation layer disposed between the switching element and the heat dissipation member.

14. The fixing assembly according to claim 13,
wherein the base of the heat dissipation member comprises a first step and a second step protruded outward, and
wherein the insulation layer is disposed between the first step and the second step.

15. The fixing assembly according to claim 12,
wherein the heat dissipation member has a second hole formed at a position corresponding to the first hole of the fixing member, and
wherein a screw penetrating the first hole and the second hole is disposed.

16. A fixing assembly comprising:
a heat dissipation member comprising a base on one surface thereof and a plurality of heat dissipation fins protruded from the other surface thereof; and
a fixing member being inserted from one side to the other side of the heat dissipation member,
wherein the fixing member comprises a first region in which a first hole is formed,
wherein the heat dissipation member has a second hole formed at a position corresponding to the first hole of the fixing member, and
wherein a screw penetrating the first hole and the second hole is disposed.

17. The fixing assembly according to claim 16,
wherein the heat dissipation member comprises two protruded portions being protruded in one direction from a first surface on which the first region of the fixing member is disposed, and a groove formed between the two protruded portions.

18. The fixing assembly according to claim 17,
wherein the first region of the fixing member comprises a first portion having a first length, a second portion having a second length smaller than the first length, and a catching part being in contact with one surface of the two protruded portions between the first portion and the second portion.

19. The fixing assembly according to claim 18,
wherein the second length of the second portion is formed to correspond to the groove of the heat dissipation member.

20. The fixing assembly according to claim 16, further comprising:
a switching element disposed on the base of the heat dissipation member.
